(19) United States
(12) Patent Application Publication
(10) Pub. No.: US 2020/0228032 A1
(43) Pub. Date: Jul. 16, 2020

(54) SYSTEM AND DEVICE FOR COLLECTING PIEZOELECTRIC ENERGY

(71) Applicant: CONSEJO SUPERIOR DE INVESTIGACIONES CIENTIFICAS, Madrid (ES)

(72) Inventors: Gonzalo MURILLO RODRIGUEZ, Cerdanyola del Valles (Barcelona) (ES); Jaume ESTEVE TINTO, Cerdanyola del Valles (Barcelona) (ES); Jorge SACRISTAN RIQUELME, Cerdanyola del Valles (Barcelona) (ES)

(21) Appl. No.: 15/757,965

(22) PCT Filed: May 20, 2016
(86) PCT No.: PCT/ES2016/070381

§ 371 Date: Mar. 6, 2018

(30) Foreign Application Priority Data
Jun. 24, 2015 (ES) P201530896

(51) Int. Cl. H02N 2/18; H01L 27/20; H01L 41/04; H01L 41/08; H01L 41/113; H01L 41/18

(52) U.S. Cl. CPC H02N 2/186; H02N 2/181; H01L 27/20; H01L 41/183; H01L 41/0815; H01L 41/1136; H01L 41/042

(57) ABSTRACT

A piezoelectric mechanical energy harvesting device is disclosed. The device is driven by environmentally-available mechanical energy. The device is an out-of-plane cantilever-based piezoelectric energy harvester based on ZnO nanostructures monolithically integrated with Schottky diodes and an entire-chip capacitor. ZnO will be utilized in two different forms: nanowires (NWs) and nanosheets (NSs). These nanostructures will be grown by a silicon-friendly hydrothermal process and using part of the top capacitor electrode as seed layer. A step-by-step process flow is proposed to integrate monolithically in a same device. This integration will allow reduced power losses and ease the combination of several generators without concerns about the stress and charge signs.

### FIELD OF INVENTION

The present invention belongs to the field of electronics and, more specifically, to nano-scale piezoelectric devices for harvesting mechanical energy.

### STATE OF THE ART

There is a need for electrical generators that are capable of providing power with high impact resistance and quality factor.

Prior MEMS devices (MEMS stands for microelectromechanical systems) use standard AlN thin-film and have disadvantages of having a limited critical fracture stress and significant rigidity that make them not optimum for ambient vibration applications. Moreover, so far, they required external control and power management circuitry that makes difficult their integration and large scale manufacturing.

Recently, it was proposed an approach based on piezoelectric nanofibres. Nevertheless this prior device has several disadvantages: low fibre surface density, low integration capability, difficult to obtain a large number of aligned fibers, substrate contamination due to nitration/oxidation of fibres. In addition, it requires a complex technological development (electro-spinning). Also, this device is less compatible with VLSI (Very large Scale Integration) silicon technologies.

ZnO nanowires have being used as piezoelectric material in the last years, because they can be grown in an economic and easy way by hydrothermal method. Main application has been energy harvesting and sensors, but the devices have been mainly bulky macroscopic devices dedicated to generate as much power as possible. However, MEMS technology has not been exploited to successfully combine these nanostructures with micro-scale movable devices to target the small energy niche offered by ambient vibrations.

US20050134149A1 proposes a piezoelectric vibration harvesting device having a cymbal stack structure with a proof mass on top. This proposal is different to the present invention, in addition to its layout, in that the proposed invention uses ZnO nanostructures as main piezoelectric material instead of thin-films. In addition, the devices according to the invention can monolithically integrate diodes and capacitors.

### BRIEF DESCRIPTION OF THE INVENTION

The invention is devoted to develop a silicon-friendly family of piezoelectric nanostructured devices with integrated rectification and buffer charge-storage capacitor able to harvest energy from mechanical motions.

According to the invention, a piezoelectric energy harvesting device comprises an anchored part, an inertial mass and a movable flexible structure. The flexible structure comprises a piezoelectric layer with a plurality of nanostructures. A capacitor is formed between a bottom electrode of a highly doped region and a top electrode of a metal layer and a diode is formed between the said metal layer and a lightly doped region in the anchored part, the diode is in-series with the capacitor.

Preferably, the flexible structure is a cantilever beam between the anchored part and the inertial mass however other movable structures are possible. For instance, a clamped-clamped beam, a serpentine suspension, a membrane or other elastic element that can play the role of spring.

The cantilever beam is designed to bend thereby causing the piezoelectric nanostructures to generate a piezopotential-driven current rectified by the diode and stored by the capacitor.

Preferably, a seed layer comprising Au is formed under the piezoelectric layer made of ZnO to grow nanowires as nanostructures. Preferably, the length of nanowires is from 100 nm to 10 μm.

Alternatively, a seed layer comprising AlN is formed under the piezoelectric layer made of ZnO to grow nanosheets as nanostructures. Preferably, the diameter of nanosheets rates from 100 nm to 10 μm.

The electrodes of the capacitor extend from the cantilever beam to the anchored part but, preferably they can be extended to cover the entire available die surface to maximize the capacitance value.

Preferably, the substrate material is n-type crystalline silicon.

Alternatively, the substrate material is p-type crystalline silicon.

According to the invention, an energy harvesting system is also proposed. The system comprises an array of piezoelectric energy harvesting devices, wherein neighboring devices are stacked by leaving a gap in between for the motion of the inertial mass.

Preferably, the energy harvesting devices are combined in-series.

Alternatively, the energy harvesting devices are combined in-parallel.

In sum, a new approach is proposed to produce piezoelectric MEMS energy harvesters also referred to as scavengers MEMS. The proposed devices are based on nanowires (NWs) and nanosheets (NSs) as piezoelectric material with a monolithically integrated diode and capacitor in a silicon-friendly technology.

In some embodiments ZnO is chosen as a low-cost solution to grow NWs and NSs by hydrothermal method. ZnO also provides a higher supported stress, enhanced flexibility and reduced manufacturing cost. At the same time, it is much easier to integrate with silicon than other nanostructure-based approaches. The device allows an out-of-plane motion when mechanically excited.

The proposed energy harvesting device contains a Schottky diode and capacitor monolithically integrated besides the piezoelectric nanogenerator which allow an in-situ signal rectification and buffer charge storage.

Positively, several energy harvesting devices can be combined to maximize the extracted power without concerns about AC output signal phases. The trade-off between size and number of energy harvesting devices shows that several smaller devices targeting different resonance frequencies can get higher generated power density than a bigger single unit with the same overall size.

The invention has further advantages: an overall higher flexibility and lower fracture risk, better performance and integrated rectification and storage. This combination of power output with reliability improves the known state of the art devices.

These and other aspects of the invention will become apparent from the drawings and exemplary embodiments.

### BRIEF DESCRIPTION OF THE DRAWINGS

A series of drawings which aid in better understanding the invention and which are expressly related with embodiments of said invention, presented as a non-limiting example thereof, are very briefly described below.

FIG. 1: Functional device configuration. (Left) A cantilever structure for mechanical out-of-plane motions, with the two different ZnO nanostructures for piezoelectric transduction: nanowires (right-down) and nanosheets (right-up)

FIG. 2: Several views of ZnO nanowires. FIG. 2a is an overall view. FIG. 2b is a detailed view. FIG. 2c shows a top view of nanosheets. FIG. 2d shows a tilted view.

FIG. 3 is an Scanning Electron Microscopy (SEM) image of ZnO NW grown over Au (left) and hexagonal ZnO nanosheets grown over AlN layer (center) and Selective Area Electron Diffraction (SAED) image corresponding to a single ZnO nanosheet generated by Transmission Electron Microscopy (TEM).

FIG. 4 is an X-Ray Diffraction (XRD) measurement of ZnO nanosheets grown over an AlN seed layer.

FIG. 5 is a cross section of the final device built on an SOI substrate.

### DETAILED DESCRIPTION

Several embodiments will be discussed for a better understanding of the invention. As indicated before, one of the goals of this invention is to make the energy harvester robust enough, able to work in a reliable way under the imposed conditions. For this purpose, piezoelectric nanostructures, also known in general as nanogenerators (NGs), are adopted instead of thin-films.

The approach takes advantage of ZnO as transduction material to convert the mechanical energy coming from the input accelerations present in the environment for two different cases. Two types of ZnO nanostructures will be integrated to obtain usable devices: nanowires (NWs) and nanosheets (NSs).

Both NWs and NSs can be generated sharing almost the same fabrication process:

These ZnO nanostructures have the particularities of using:
the whole die surface to manufacture the storage capacitor,
the top electrode of this capacitor as seed layer to grow the ZnO nanostructures on top of the cantilever to be bent, and
a small undoped silicon die region are to monolithically integrate Schottky diodes.

### Device Layout

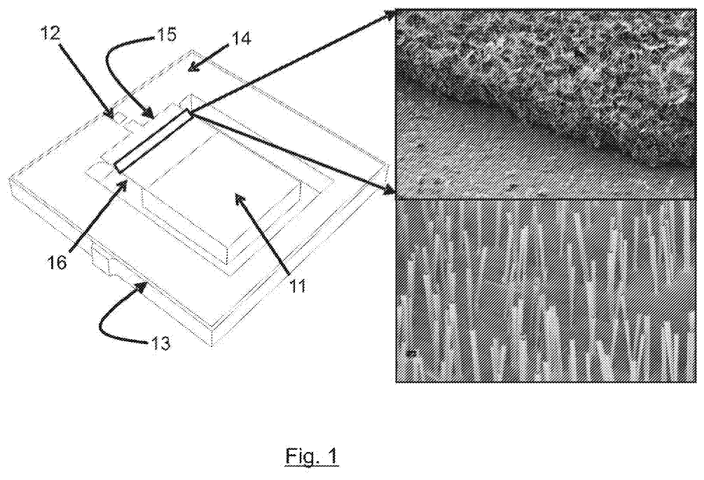

FIG. 1 shows the configuration of one of the final devices. The common configuration of the different design versions is based on a cantilever architecture, because current silicon-based piezoelectric harvesters show the best performance with a spring-mass system. However, other suspensions, such as clamped-clamped beams, serpentine flexures, membranes or other elastic elements can be used instead of cantilever beam.

Inertial mass 11 is connected through a cantilever beam 16 to rest of the device die 13. On top of this cantilever, there is a piezoelectric layer 15 made of ZnO nanostructures. Monolithically integrated in the same die 13, there is a Schottky diode 12 and a capacitor 14.

Several sizes will be generated to get different resonance frequencies, and combined to obtain multifrequency arrays of energy harvesters. The typical lateral dimensions of the cantilevers and inertial mass will rate from 0.5 to 5 mm, and the target thickness of the piezoelectric layer will be around 1 μm for the first prototype. The harvesters can be combined to produce an array according to series or parallel combination of them. Depending on this electrical combination, increment of output current or voltage levels will be obtained for series and parallel combinations respectively. In order to physically combine the devices, they can be stacked by leaving enough space in between for the inertial mass resonant motion.

As illustrated in FIG. 5, the spring is built by means of silicon beams microstructured on the SOI device layer and covered by the different piezoelectric material that plays the role of mechanical spring and transductor. The inertial mass 11 is created by etching both top and bottom silicon layer of the SOI (Silicon On Insulator) wafer by RIE (Reactive Ion Etching) and DRIE (Deep Reactive Ion Etching) respectively. The non-etched part which corresponds to the frame off the die that will form the anchored part 17.

The use of an SOI wafer, eases the definition of cantilever beam 16 and the inertial mass 11. This wafer will be n-type in order to be able of integrating a Schottky diode 12 and a capacitor 14 together with the movable structure. The diode 12 will have the role of rectifying, with low losses, the AC signal generated by the NGs which at the same time will be grown just on top of the large surface of the capacitor 14 to save area.

This configuration creates a network of a diode 12, piezoelectric AC layer 15 as generator and a capacitor 14 in series, therefore for each mechanical stimulation on the NGs, negative charges will be stored in the capacitor 14. Due to the in-situ rectification, different designs with different sizes can be connected together and the voltage output will be always added. For instance, longer cantilever 13 and/or bigger inertial masses 11 will result on lower resonance frequencies and thicker beams and/or stiffer materials will increases the resonance frequencies.

### Materials

These devices use an SOI wafer as main structural part. The substrate is chosen in order to facilitate the inertial mass and beam definitions. Then two different piezoelectric materials are used:

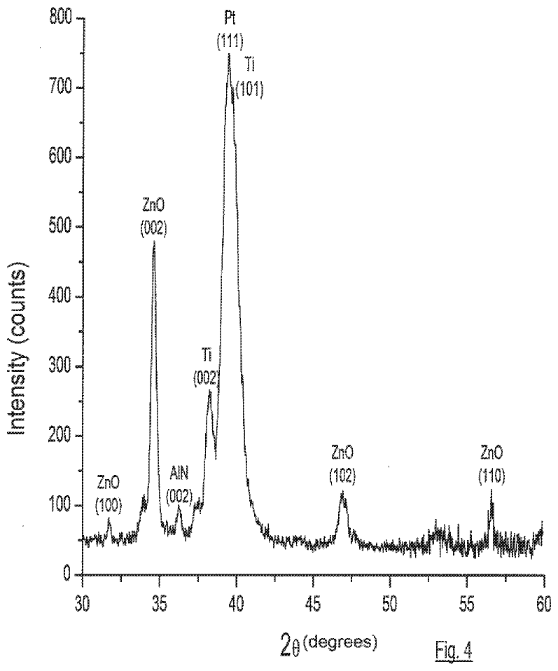

AlN: This piezoelectric material has been used for several years to fabricate FBARs (Film Bulk Acustic-wave Resonator) and energy scavengers. AlN is used as seed layer to grow ZnO NSs which will conform a functional nanostructured piezoelectric layer. AlN is processed by RF sputtering on top of a thin layer of Ti/Pt which infers a good crystalline orientation. Thin layers of less than 100 nm can be deposited and XRD analysis of FIG. 4 shows that the crystalline structure and orientation are stable. The final thicknesses used in this type of devices may be between 10 nm and 1 um.

ZnO: This piezoelectric and semiconductor material will be used to grow nanostructures, specifically on piezoelectric ZnO nanowires (NWs) and nanosheets (NSs). ZnO NGs have been used for energy harvesting in the last years. These nanostructures have the advantages of being more flexible, less sensitive to fracture, and can be actuated easier than thin-films. The growth method is based on a hydrothermal chemical reaction at low temperature (<80° C.) directly on the silicon substrate covered by a seed layer. This growth method is especially fast, easy, inexpensive and fully compatible with wafer-level silicon-based microelectronics technologies.

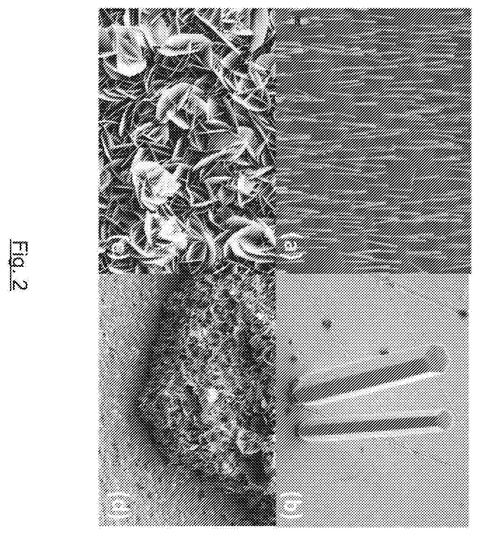

FIG. 2 shows the two types of ZnO nanostructures that will be used to fabricate the devices.

For the case of NSs, a thin layer of AlN (thickness can be smaller than <100 nm) is used as seed layer, anti-screening carrier barrier and additional piezoelectric material. In this way, the thin layer of AlN should not affect the mechanical properties of the device because the created stress scales down with the thickness. The growth method for ZnO NSs is the same as for the NWs, but a different seed layer is used totally affecting the grown nanostructure shape. The main point that makes this nanostructure a promising solution for NG is the high uniformity, reproducibility and rapidness of the NS growth. Several studies have been carried out in order to verify that ZnO NSs grown over AlN have a good crystallinity and therefore piezoelectric properties.

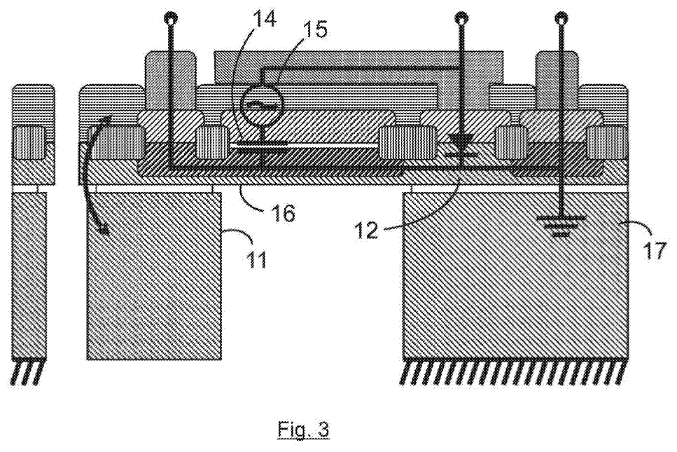

FIG. 3 shows the result of a Selected Area Electron Diffraction (SAED) generated in a TEM of a single NS layer were a high crystallinity of the material can be noticed. It can be also observed in FIG. 3 that the growth direction is perpendicular to the c-axis, in contrast to a typical ZnO NW which grows along the c-axis. In case of NS, it can be observed a (0001) preferential growth plane at the expense of the inhibition of {1010} the growth plane, which is fully inverse in case of NW. Moreover, the hexagonal size of the ZnO crystals, typical of a wurtzite lattice, is clear. The hexagonal crystal can have a diameter of more than 1-5 μm and a thickness of less than 20 nm which means a huge aspect ratio larger than 100.

A XRD study was also performed to observe other crystalline orientations present in a matrix of NSs. The result can be seen in FIG. 4. An outstanding peak can be observed for the desired (002) orientation of the ZnO, also the contribution of the AlN thin film is clearly visible.

### Process Flow

As already mentioned, a capacitor and a diode will be integrated together with the energy harvester in order to have a compact system able to get a DC voltage from a variable input acceleration. The fabrication process is addressed to be compatible with low demanding CMOS technologies.

The process steps to be followed to carry out the technological fabrication, including seven photolithographic steps, are listed below:

1. An n+ implantation is performed in selected areas of the n-doped SOI device layer through a protection oxide previously grown. This implantation will define the Ohmic contact with silicon and the bottom electrode of the capacitor. (N+ mask)
2. A field oxidation of 1060 nm is carried out in order to passivate the different devices. By means of Reactive Ion Etching (RIE) and wet etch this oxide can be selectively removed to define active regions. (Active area mask)
3. Performing of gate oxidation of 365 Å at 950° C. to create the thin oxide layer needed to make the capacitor.
4. Removing this thin oxide through dry and wet etches from contact areas to allow electrical access to the different contacts. (Contact mask)
5. On top of these contact areas, a multilayer of Cr/Ni/Au will be sputtered to create the capacitor top electrode, the metal-semiconductor interface of the Schottky diode and the metallic contacts. The capacitor electrode can be designed to cover the entire available die surface to maximize its charge capacity which is a great improvement compared to state-of-the-art devices. The last exposed Au layer will be also used as seed layer to grow ZnO NWs.
6. In order to fabricate the version of this device based on ZnO NS, a Ti/Pt layer followed by an AlN layer of 100 nm will be deposited by RF sputtering to generate the seed layer for these nanostructures.
7. The total metal stack and seed layer when applicable, is etched afterwards in selected areas. (Metal1 mask)
8. ZnO nanowires and nanosheets will be grown by a hydrothermal process on the respective seed layers deposited over capacitor top electrode which makes this device unique.
9. A layer of polymer (e.g. PMMA, PDMS or SU8), will be spin coated over the surface and developed to embed the NWs/NSs to avoid short-circuits between NG electrodes, if needed.
10. A thick layer of aluminum will be deposited (also other metals such as titanium and platinum can be used), patterned and etched to cover the embedded NWs/NSs, creating the upper NG electrode. (Metal2 mask).
11. The outline of the movable structures is patterned on the device side (RIE-front mask) and the SOI device layer is etched through by RIE.
12. On the back side, aluminum is deposited, patterned and etched to create a hard-mask for the DRIE. (DRIE-back mask).
13. The SOI handle wafer is fully etched by DRIE down to the buried oxide. A protective resist is coated on the front side before performing this step.
14. The structures are carefully released by wet etching of the SiO₂ and the resist coating is dissolved by acetone immersion.

The final device is a released tip-loaded piezoelectric cantilever beam with integrated capacitor and diode as shown in FIG. 5. This integration allows reduced power losses and eases the combination of several generators without the need of controlling the phase differences of the generated piezopotentials (i.e. no resonant motion synchronization is necessary).

### Performance

For the device based on ZnO NWs, we take the assumption that the density of NWs will be ˜4 NW/μm². If every NW takes an active part in the charge generation, and from a value of 4 pW/NW measured when a NW is bent by an AFM tip [4], it can be estimate a generated power of ˜1.6 mW/cm². However, in our case the mechanical stimulation will be produced by the compression of the NW arrays derived from the beam bending and a typical transduction surface of 1 mm². A power output of 1.45 mW/cm² (for transduction area of ˜4 mm²) has been reported for a structure similar to the one which will be placed on top of the integrated capacitor for pressure levels similar to the achieved with the cantilever beam bending. Taking into account our device configuration (transduction area of ˜1 mm², acceleration of 1-10 g, main stress of 1-10 MPa), a target output power of 500 pW/cm² is a reasonable value. For the case of NSs, no previous data is available, but comparable power densities are expected because of the similar dimensions and crystal configuration of both NWs and NSs.

From previous results, obtained by using similar structures but with a thin-film approach, we can estimate a lower limit value for our prototypes.

For the first prototype, the dimensions of the final devices will be 0.5×0.5×0.05 cm³, and they will be based on an n-type SOI wafer. A frame or holder made of glass or silicon is expected to be used in order to allow the inertial mass to move up and down. This support frame could increase the thickness of the final device by 0.05 cm.

### NUMERALS

11 Inertial mass.
12 Schottky diode.
13 Device die.
14 Capacitor.
15 Piezoelectric layer.
16 Cantilever beam.
17 Anchored part.

1. A piezoelectric energy harvesting device, comprising:
an anchored part;
an inertial mass;
a flexible structure;
characterized in that:
the flexible structure comprises a piezoelectric layer with a plurality of nanostructures;
a capacitor is formed between a bottom electrode of a heavy doped region and a top electrode of a metal layer; and
a diode is formed between the said metal layer and a light doped region in the anchored part, the diode is in-series with the capacitor,
wherein the flexible structure is configured to bend thereby causing the piezoelectric nanostructures to generate a piezopotential-driven current rectified by the diode and stored by the capacitor.

2. The device according to claim 1, wherein the movable structure is a cantilever beam between the anchored part and the inertial mass.

3. The device according to claim 1, wherein a seed layer comprising Au is formed under the piezoelectric layer made of ZnO and the nanostructures are nanowires.

4. The device according to claim 3, wherein the length of nanowires is from 100 nm to 10 μm.

5. The device according to claim 1, wherein a seed layer comprising AlN is formed under the piezoelectric layer made of ZnO and the nanostructures are nanosheets.

6. The device according to claim 5, wherein the diameter of nanosheets rates from 100 nm to 10 μm.

7. The device according to claim 1, wherein the electrodes of the capacitor extends from the flexible structure to the anchored part.

8. The device according to claim 1, wherein the substrate material is n-type crystalline silicon.

9. The device according to claim 1, wherein the substrate material is p-type crystalline silicon.

10. An energy harvesting system comprising an array of piezoelectric energy harvesting devices according to claim 1, wherein neighboring devices are stacked by leaving a gap in between for the motion of the inertial mass.

11. The system according to claim 10, wherein the energy harvesting devices are combined in-series.

12. The system according to claim 10, wherein the energy harvesting devices are combined in-parallel.
